(19) United States
(12) Patent Application Publication
(10) Pub. No.: US 2004/0005746 A1
(43) Pub. Date: Jan. 8, 2004

(54) Method of manufacturing a MOS transistor

(76) Inventor: Lien-Che Ho, Hsinchu (TW)

Correspondence Address: MARTINE & PENILLA, LLP, 710 LAKEWAY DRIVE, SUITE 170, SUNNYVALE, CA, 94085, US

(21) Appl. No.: 10/188,474

(22) Filed: Jul. 3, 2002

(51) Int. Cl. H01L 21/336

(52) U.S. Cl. 438/197

(57) ABSTRACT

A method of manufacturing MOS transistors is disclosed. The method includes a step of depositing a shield layer on a silicon substrate prior to forming source/drain regions. The shield layer is formed to cover a gate electrode and a field oxide layer (or shallow trench isolation) on a silicon substrate with a uniform thickness. Then, the silicon substrate is heavily implanted. The implanting energy is controlled to prevent ions from penetrating the shield layer at the sidewall region of the gate electrode. After removing the shield layer, the silicon substrate is processed with lightly implantation. In this way, a MOS transistor with LDD is formed with less manufacturing steps.

### BACKGROUND OF THE INVENTION

1. Field of the Invention

The present invention relates to a method of manufacturing a MOS transistor, especially to a method of forming LDD with fewer manufacturing steps.

2. Description of the Related Art

In a MOS transistor, channel length represents the distance between a source region and a drain region. To minimize the size of MOS transistors, the channel length must be reduced. However, persons skilled in the art would know the shortened channel length causes “Hot Electron Effects” and affects the performance of transistors. In order to avoid this problem, a reduced doping gradient is formed between source/drain and channel as Lightly Doped Drain (LDD).

FIG. 1a to FIG. 1g illustrates a conventional method for manufacturing LDD in a MOS transistor.

First, a gate oxide 101, a gate electrode 102, and a field oxide layer 103 are formed on a p-type silicon substrate 100 with traditional semiconductor process, as shown in FIG. 1a. Next, a photoresist layer is coated onto the surface of the silicon substrate 100. Then, the photoresist layer is exposed with a first photo mask (not shown). After a development process, a first photoresist pattern 105 is formed on the silicon substrate 100. Referring to FIG. 1b, the surface of the substrate 100 not covered by the first photoresist pattern 105 is implanted with low-concentration phosphor ions 104 (N⁻ doped). After forming the lightly doped regions 106 on the substrate 100, the first photoresist mask 105 is removed, see FIG. 1c.

Next referring to FIG. 1d, a silicon dioxide (SiO₂) layer 107, is deposited on the substrate surface with Low Pressure Chemical Vapor Deposition Method (LPCVD). The silicon dioxide layer 107 is then etched anisotropically. As show in FIG. 1e, spacers 117 are formed at the two sides of the gate electrode 102.

Next, a photoresist layer is coated on the substrate 100 again. The photoresist layer is exposed with a second photo mask (not shown) to form a second photoresist pattern 115, as shown in FIG. 1f. Then, the silicon substrate surface not shaded by the second photoresist pattern 115 is implanted with high-concentration arsenic ions 114 (N⁺ doped). After forming the heavily-doped regions 116 on the substrate 100, the second photoresist mask 115 is removed, see FIG. 1g. In this way, a MOS transistor with LDD is formed.

As described above, the traditional process for forming LDD in MOS transistors requires two photo masks, i.e., the first photo mask and the second photo mask. That is, the photoresist-coating, exposure and development processes are all required in the lightly-doped region and the heavily-doped region forming steps, respectively. This makes the manufacturing process of MOS transistors more complicated.

### SUMMARY OF THE INVENTION

Therefore, one object of the invention is to provide a method for manufacturing MOS transistors. The method can reduce the manufacturing steps in forming lightly-doped region and heavily-doped regions.

In accordance with the present invention, the method includes the steps of: forming a gate oxide, a gate electrode and a field oxide layer on a substrate;

depositing a shield layer on the substrate to cover the gate electrode, the field oxide and the substrate surface with a uniform thickness, wherein the shield layer forms sidewall regions beside the gate electrode that have a thickness larger than the uniform thickness;

forming a resist pattern on the substrate to cover the field oxide layer;

implanting ions into the substrate to form heavily doped regions, wherein the implanting energy is controlled so that the ions cannot penetrate through the shield layer at the sidewall regions;

removing the shield layer not covered by the resist pattern; implanting ions into the substrate to form lightly doped regions on the substrate; and

removing the resist pattern and the residual shield layer.

According to another aspect of the present invention, shallow trench isolation can be formed as device isolation area to replace the field oxide layers.

The method of the present invention requires only one mask in LDD forming step. Meanwhile, the method of the invention omits the step of forming a spacer.

The objects, features and advantages of the present invention will become more apparent with reference to the accompanying drawings and the following detailed descriptions.

### BRIEF DESCRIPTION OF THE DRAWINGS

FIG. 1a to FIG. 1g are cross-sectional views showing a method of forming a MOS transistor according to the prior art; and

FIG. 2a to FIG. 2f are cross-sectional views showing a method of forming a MOS transistor according to the preferred embodiment of the invention.

FIG. 3 is a cross-sectional view showing a conventional MOS transistor with shallow trench isolation.

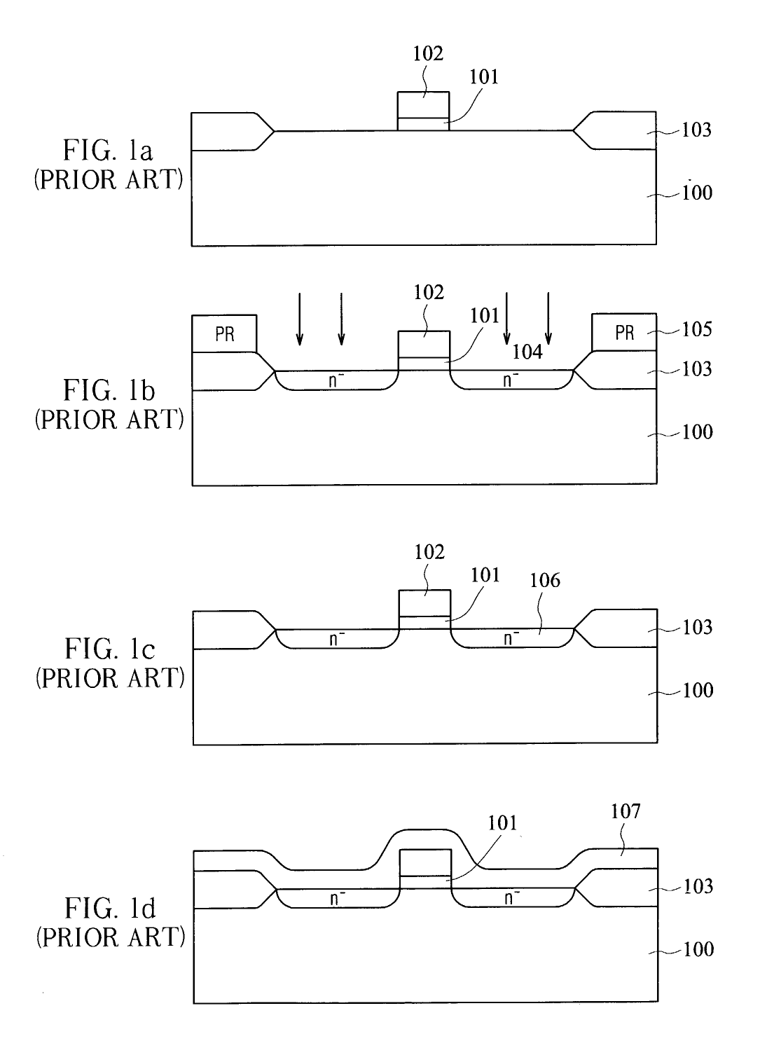

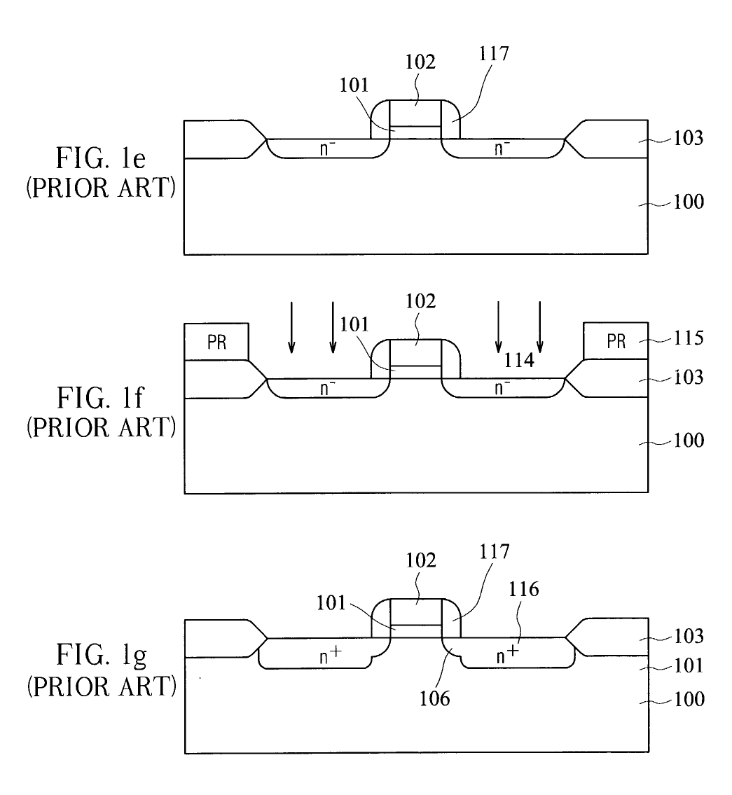

### DETAIL DESCRIPTION OF THE INVENTION

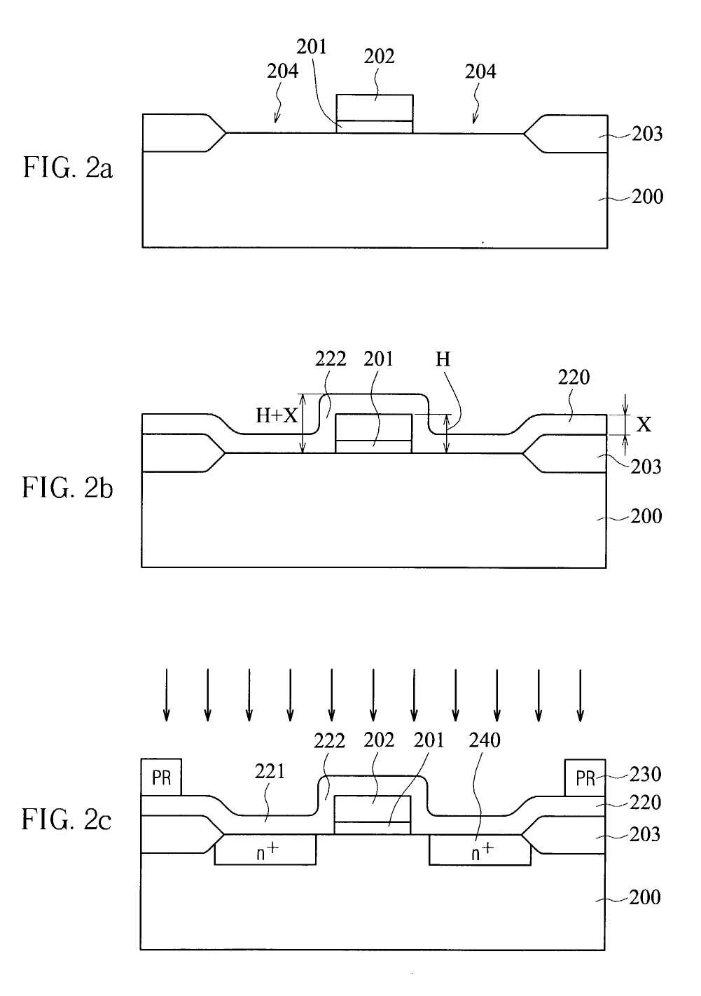

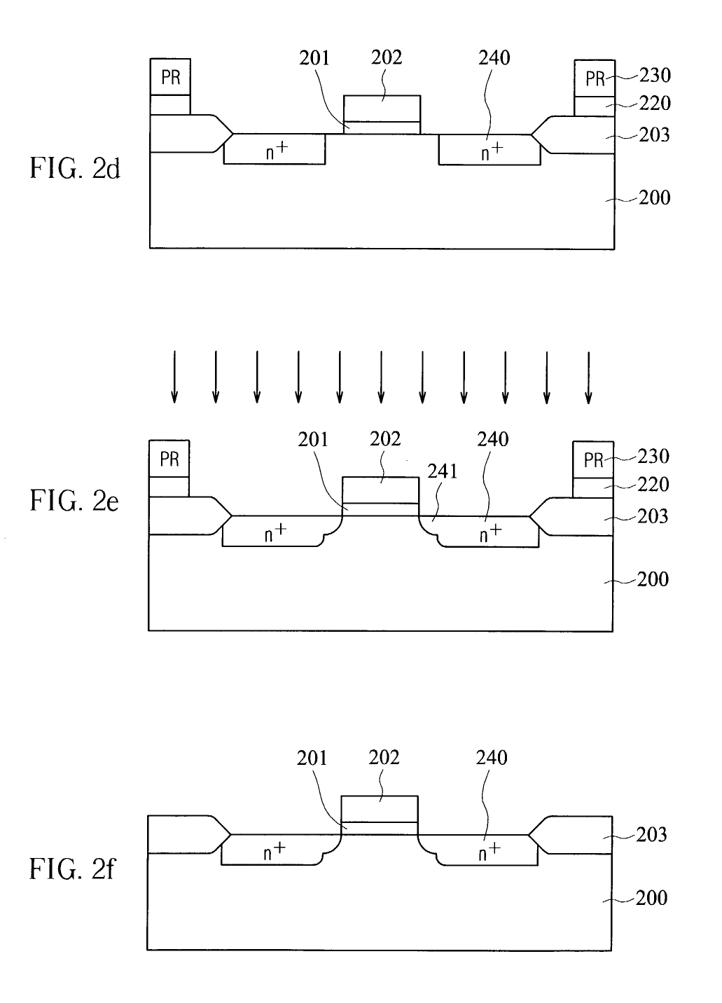

FIG. 2a to FIG. 2f illustrate a manufacturing method of MOS transistors according to a preferred embodiment of this invention.

Referring to FIG. 2a, a gate oxide 201, a gate electrode 202 and field oxide layer 203 are formed on a p-type silicon substrate 200 by a conventional process. The exposed silicon surface 204 is used to form source/drain regions of a MOS transistor in the following steps. In this embodiment, the gate electrode 202 is formed of polysilicon and the field oxide layer 203 is formed of silicon dioxide with wet-oxidation method.

According to the invention, prior to the source/drain region forming steps, a shield layer 220 is deposited on the substrate surface, as shown in FIG. 2b. The shield layer 220 is formed of materials having good step-coverage, such as BARC (bottom anti-reflective coating). Since the property of good step-coverage, the shield layer 220 covers the gate electrode 202, the field oxide layer 203 and the silicon substrate surface 204 with a uniform thickness. The shield layer 220 can be formed of organic materials. Besides, the shield layer 220 can be formed of inorganic materials, such as amorphous carbon, silicon nitride (SIN), silicon oxynitride (SiOₓN_{y}) or titanium oxide (TiO).

Since the shield layer 220 covers the gate electrode 202, the field oxide layer 203 and the substrate surface with an uniform thickness, its vertical thickness at the sidewall regions 222 of the gate electrode 202 is much larger than its thickness at the silicon surface 204. As shown in the figure, assume that the thickness of the shield layer 220 at the substrate surface is X, then its thickness at the sidewall region 222 equals the height of the gate electrode 202 plus the thickness at substrate surface, i.e., H+X. This feature facilitates the process of forming an LDD region.

Next, a photoresist layer is coated onto the surface of the substrate 200. The photoresist layer is exposed with a photo mask by photolithography technology to form a photoresist pattern 230. In this embodiment, the photoresist layer is formed of a positive photoresist. Subsequently, by using the photoresist pattern 230 and the shield layer 220 as masks, the substrate 200 is implanted to form heavily doped regions 240, as shown in FIG. 2c. In this embodiment, the heavily doped ions can be n-type dopants, such as arsenic ions.

As described above, the vertical thickness of the shield layer 220 at the sidewall region 222 is much larger than its thickness at the substrate surface 204. Thus, the implant energy is controlled so that the ions cannot penetrate through the shield layer 220 at the sidewall regions 222 of the gate electrode 202. In other words, there are no ions implanted into the silicon substrate 200 under the sidewall region 222.

Referring to FIG. 2d, the shield layer 220 not shaded by the photoresist pattern 230 is etched away.

Then, referring to FIG. 2e, the silicon substrate 200 is implanted to form lightly doped regions 241 by using the photoresist pattern 230 as a mask. As shown in the figure, the silicon substrate under the sidewall regions 222 of the gate electrode 202 is exposed after removing the shield layer and is implanted to form the lightly doped regions 241. In this embodiment, the lightly doped ions can be n-type dopants, such as phosphor ions.

Finally, the photo resist 230 and the residual shield layer 220 are etched away. In this way, a MOS transistor with LDD is formed. The highly doped regions 240 and the lightly doped regions 241 at the two sides of the gate electrode 202 are used as the source/drain regions of the MOS transistor.

It is clear from FIG. 2a to FIG. 2f that the invention utilizes only one photo mask in forming the heavily doped regions and the lightly doped regions. Moreover, the invention further omits a spacer-forming step of the conventional process. Therefore, the method of the invention simplifies the manufacturing process of MOS transistors effectively. The invention can improve the product throughput and reduce the manufacturing cost.

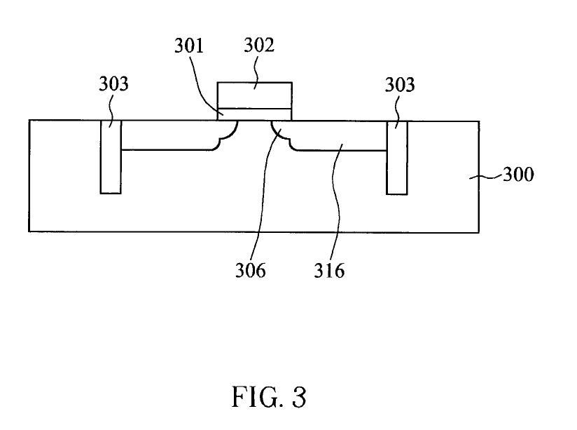

Besides, although p-type substrates and n-type dopants are used in the present invention, persons skilled in the art would know that n-type substrates and p-type dopants also can be used in the present invention. Meanwhile, although the present invention utilizes field oxide layers as device isolation area, persons skilled in the art would know that shallow trench isolation (STI) also can be formed as device isolation area, as shown in FIG. 3. In the figure, the shallow trench isolation is denoted as 303.

While preferred embodiments of the present invention have been described above, such description is for illustrative purposes only, and it is to be understood that changes and variations may be made without departing from the spirit or scope of the following claims.

What is claimed is:

1. A method of manufacturing a MOS transistor, comprising the steps of:
forming a gate oxide, a gate electrode and a field oxide layer on a substrate;
depositing a shield layer on said substrate to cover said gate electrode, said field oxide and said substrate surface with an uniform thickness, wherein said shield layer forms sidewall regions beside the gate electrode that has a thickness larger than the uniform thickness;
forming a resist pattern on said substrate;
implanting ions into said substrate to form heavily doped regions, wherein the implanting energy is controlled so that the ions cannot penetrate through said shield layer at the sidewall regions;
removing said shield layer not covered by said resist pattern;
implanting ions into said substrate to form lightly doped regions on said substrate; and
removing said resist pattern and said residual shield layer.

2. The method of claim 1, wherein said substrate is p-type silicon substrate and said gate electrode is made of polysilicon.

3. The method of claim 2, wherein said implanting ions are n-type dopants.

4. The method of claim 1, wherein said substrate is n-type silicon substrate and said gate electrode is made of polysilicon.

5. The method of claim 4, wherein said implanting ions are p-type dopants.

6. The method of claim 1, wherein said shield layer is made of made of BARC (bottom anti-reflective coating).

7. The method of claim 1, wherein said shield layer is made of organic material.

8. The method of claim 1, wherein the material of said shield layer is selected from the group of: amorphous carbon, silicon nitride (SIN), silicon oxynitride (SiOₓN_{y}) and titanium oxide (TiO).

9. A method of manufacturing a MOS transistor, comprising the steps of:
forming a gate oxide, a gate electrode and shallow trench isolation (STI) on a substrate;
depositing a shield layer on said substrate to cover said gate electrode, said field oxide and said substrate surface with an uniform thickness, wherein said shield layer forms sidewall regions beside the gate electrode that has a thickness larger than the uniform thickness;
forming a resist pattern on said substrate;
implanting ions into said substrate to form heavily doped regions, wherein the implanting energy is controlled so that the ions cannot penetrate through said shield layer at the sidewall regions;
removing said shield layer not covered by said resist pattern;
implanting ions into said substrate to form lightly doped regions on said substrate; and
removing said resist pattern and said residual shield layer.

10. The method of claim 9, wherein said substrate is a p-type silicon substrate and said gate electrode is made of polysilicon.

11. The method of claim 10, wherein said implanting ions are n-type dopants.

12. The method of claim 9, wherein said substrate is an n-type silicon substrate and said gate electrode is made of polysilicon.

13. The method of claim 12, wherein said implanting ions are p-type dopants.

14. The method of claim 9, wherein said shield layer is made of made of BARC (bottom anti-reflective coating).

15. The method of claim 9, wherein said shield layer is made of organic material.

16. The method of claim 9, wherein the material of said shield layer is selected from the group of: amorphous carbon, silicon nitride (SIN), silicon oxynitride (SiOₓN_{y}) and titanium oxide (TiO).
